(19) United States
(12) Patent Application Publication
(10) Pub. No.: US 2005/0068824 A1
(43) Pub. Date: Mar. 31, 2005

(54) Semiconductor memory

(76) Inventors: Shigeo Houmura, Kyoto (JP); Hiroaki Okuyama, Kyoto (JP); Hidenari Kanehara, Osaka (JP); Norihiko Sumitani, Osaka (JP)

Correspondence Address: MCDERMOTT WILL & EMERY LLP, 600 13th Street, N.W., Washington, DC, 20005-3096, US

(21) Appl. No.: 10/935,713

(22) Filed: Sep. 8, 2004

(30) Foreign Application Priority Data
Sep. 8, 2003 (JP) P2003-315191

(51) Int. Cl. G11C 7/00

(52) U.S. Cl. 365/202

(57) ABSTRACT

A semiconductor memory of the present invention comprises: a static-type memory cell constituted of a pair of access transistors formed with NMOS transistors, a pair of drive transistors formed with NMOS transistors, and a pair of load transistors formed with PMOS transistors. Further, it comprises a substrate bias control unit which applies bias for increasing access speed to a substrate of any of the transistors when making access to the memory cell through adjusting electric current flown to a memory storage node in a common junction point of the three types of transistors. A substrate potential which is appropriate for reading-out, writing, memory-storing operation and low leak is applied.

### BACKGROUND OF THE INVENTION

1. Field of the Invention

The present invention relates to a semiconductor memory having static-type memory cells.

2. Description of the Related Art

Recently, the size of a SRAM memory cell has been remarkably reduced in size in accordance with processes which have become minuter. For a transistor of the memory cell, the one with a short gate width is used, which raises the issues of deterioration in the reading-out speed and an increase in the amount of a leak current. When using a transistor with low threshold voltage for achieving high-speed reading-out, the leak current is increased. On the contrary, when using a transistor with high threshold voltage for suppressing the leak current, memory cell current is decreased so that the speed of reading-out is decreased.

In order to achieve both high-speed reading-out and low leak current, it is proposed to kinetically change substrate potential of a substrate of the memory cell. That is, at the time of writing and reading-out, forward bias is applied to substrates of a drive transistor and a load transistor for lowering the threshold voltage for achieving high-speed operations. At the time of storing data, back bias is applied to the substrates of the drive transistor and the load transistor for increasing the threshold voltage for decreasing the leak current.

However, a static noise margin (simply referred to as noise margin hereinafter), which is an index of stability of the memory cell, is deteriorated so that a possibility of causing malfunctions is increased.

Moreover, it is not the ideal setting for the drive transistor and the load transistor to reduce the threshold voltage thereof at the time of both writing and reading-out in terms of the speed of each operation, leak current and the stability.

### BRIEF SUMMARY OF THE INVENTION

The semiconductor memory of the present invention comprises:
a static-type memory cell constituted of a pair of access transistors formed with NMOS transistors, a pair of drive transistors formed with NMOS transistors, and a pair of load transistors formed with PMOS transistors; and
a substrate bias control unit which applies bias for increasing access speed to a substrate of any of the transistors when making access to the memory cell through adjusting electric current flown to a memory storage node in a common junction point of the three types of transistors.

The substrate bias control unit controls the bias applied to the transistor substrate when making access (at the time of writing and reading out) for adjusting the electric current flown to the memory storage node so as to increase the access speed. There are some patterns as will be described in the followings in the control modes of the substrate bias control unit. In any case, the substrate bias control unit controls the substrate bias to increase the access speed through adjusting the electric current flown to the memory storage node.

One of the substrate bias control modes performed through adjusting the electric current flown to the memory storage node applies back bias to a substrate of a load transistor at the time of writing data for deteriorating the capacity of holding the memory storage node to the state before writing data. In this case, the electric current of the load transistor is decreased so that the speed of writing data can be increased.

Another control mode applies back bias to a substrate of a drive transistor at the time of writing data for deteriorating the capacity of holding the memory storage node to the state before writing data. In this case, the electric current of the drive transistor is decreased so that the speed of writing data can be increased.

Still another control mode applies forward bias to a substrate of an access transistor at the time of writing data for deteriorating the capacity of holding the memory storage node to the state before writing data. In this case, the electric current of the access transistor is increased so that the speed of writing data can be increased.

Yet another control mode, when writing data, applies back bias to the substrate of the load transistor and applies forward bias to the substrate of the access transistor. In this case, the electric current of the load transistor is decreased and the electric current of the access transistor is increased so that the speed of writing data can be further increased.

Another control mode, when writing data, applies back bias to the substrate of the load transistor and applies back bias to the substrate of the drive transistor. In this case, the electric current of the load transistor and the electric current of the drive transistor are decreased so that the speed of writing data can be further increased.

Still another control mode, when writing data, applies forward bias to the substrate of the access transistor and applies back bias to the substrate of the drive transistor. In this case, the electric current of the access transistor is increased and the electric current of the drive transistor is decreased so that the speed of writing data can be further increased.

Yet another control mode, when writing data, applies back bias to the substrate of the load transistor, applies forward bias to the substrate of the access transistor, and applies back bias to the substrate of the drive transistor. In this case, the electric current of the load transistor and that of the drive transistor is decreased and the electric current of the access transistor is increased so that the speed of writing data can be further increased.

Another control mode applies forward bias to the substrates of the access transistor and the drive transistor, respectively. In this case, the electric current of the access transistor and the drive transistor is increased so that the capacity of writing data to a memory storage node is increased and the capacity of holding the memory storage node to the state before writing data is also improved relatively. Moreover, the electric current in both the access transistor and the drive transistor can be increased so that the noise margin becomes larger than the case where the forward bias is applied to the substrate of the access transistor and the back bias is applied to the substrate of the drive transistor, so that the stability of the memory cell can be improved.

Still another control mode, when writing data, applies back bias to the substrate of the load transistor, and applies forward bias to the substrates of the access transistor and the drive transistor, respectively. In this case, the speed of writing data can also be increased.

Yet another control mode applies forward bias to the substrate of the access transistor when reading out data. In this case, the electric current of the access transistor is increased so that the speed of reading out data can be increased.

Another control mode applies forward bias to the substrate of the drive transistor when reading out data. In this case, the electric current of the drive transistor is increased so that the speed of reading out data can be increased.

Still another control mode, when reading out data, applies forward bias to the substrates of the access transistor and the drive transistor, respectively. In this case, the electric current of the drive transistor and that of the access transistor is increased so that the speed of reading out data can be further increased.

Yet another control mode applies forward bias to the substrate of the load transistor when reading out data. In this case, the electric current of the load transistor is increased so that the electric current ratio between the load transistor and the drive transistor becomes large. Thus, the noise margin is increased and the stability of the memory cell can be improved.

Another control mode applies back bias to the substrate of the access transistor when reading out data. In this case the electric current of the access transistor is decreased so that the electric current ratio between the load transistor and the drive transistor becomes large. Thus, the noise margin is increased and the stability of the memory cell can be improved.

Still another control mode, when reading out data, applies forward bias to the substrate of the load transistor and applies back bias to the substrate of the access transistor. In this case, the electric current of the load transistor is increased and the threshold voltage thereof is decreased while the electric current of the access transistor is increased and the threshold voltage thereof is increased. Thus, the noise margin is further increased compared to the case where the bias is individually applied, so that the stability of the memory cell can be further improved.

Yet another control mode, when reading out data, applies forward bias to the substrate of the load transistor and applies forward bias to the substrate of the drive transistor. In this case, the electric current of the load transistor is increased and the threshold voltage thereof is decreased while the electric current of the drive transistor is increased and the threshold voltage thereof is increased. Thus, the noise margin is further increased compared to the case where the bias is individually applied, so that the stability of the memory cell can be further improved.

Another control mode, when reading out data, applies back bias to the substrate of the access transistor and applies forward bias to the substrate of the drive transistor. In this case, the electric current of the access transistor is decreased and the threshold voltage thereof is increased while the electric current of the drive transistor is increased and the threshold voltage thereof is decreased. Thus, the noise margin is further increased compared to the case where the bias is individually applied, so that the stability of the memory cell can be further improved.

Still another control mode, when reading out data, applies forward bias to the substrate of the load transistor, applies back bias to the substrate of the access transistor, and applies forward bias to the substrate of the drive transistor. In this case, the electric current of the load transistor and that of the drive transistor is increased and the threshold voltage thereof is decreased while the electric current of the access transistor is decreased and the threshold voltage thereof is increased. Thus, the noise margin is further increased compared to the case where the bias is individually applied, so that the stability of the memory cell can be further improved.

Yet another control mode, when reading out data, applies back bias to the substrates of the access transistor and the drive transistor, respectively. In this case, the electric current of the access transistor and the drive transistor is decreased so that the electric current ratio between the load transistor and the drive transistor becomes large. Thus, the stability of the memory cell can be improved.

Another control mode, when reading out data, applies forward bias to the substrate of the load transistor, and applies back bias to the substrates of the access transistor and the drive transistor, respectively. In this case, the electric current of the load transistor is increased and the threshold voltage thereof is decreased while the electric current of the access transistor and that of the drive transistor is decreased and the threshold voltage thereof is increased. Thus, the stability of the memory cell can be further improved.

The above-described configuration of the static-type memory cell, i.e. a pair of drive transistors formed with the NMOS transistors, a pair of drive transistors formed with the NMOS transistors and a pair of load transistors formed with the PMOS transistors, is simply referred to as a basic configuration A hereinafter.

In the basic configuration A, the transistor substrate of the memory cell is separated by a column unit or a row unit, and the substrate bias control unit applies:
bias by an appropriate mode among the above-described modes for increasing writing speed to transistor substrates of a selected column or a selected row in the memory cell when writing data;
bias by an appropriate mode among the above-described modes for increasing reading-out speed to the transistor substrates of the selected column or selected row in the memory cell when reading out data; and
bias by an appropriate mode among the above-described modes for improving stability to transistor substrates of an unselected column or an unselected row in the memory cell.

In this case, separate electric potential can be applied to the transistor substrate in the memory cell by a column unit or to the transistor substrate of the selected row in the memory cell so that it enables to perform the control which is appropriate for the operation of each column or each row. That is, the bias is applied only to the column or row which is the target of writing data at a high-speed so as to increase the speed of writing data. Also, at the time of reading out data, the bias is applied only to the column or row from which the data is to be read out at a high-speed so as to increase the speed of reading out data. The substrates to be controlled are the column or the row to which data is written or the column or the row from which the data is to be read out, so that application of the bias itself can be performed at a high speed. The stability of the unselected columns and the unselected rows of the memory cell with no access being made can be improved. Moreover, when applying the back bias to the unselected columns or the unselected rows of the memory cell, the leak current of the unselected columns or the unselected rows of the memory cell can be decreased.

Further, in the basic configuration A, the substrate bias control unit comprises: a high-speed writing mode which applies bias for increasing writing speed to the transistor substrate of the memory cell; a high-speed reading-out mode which applies bias for increasing reading out speed to the transistor substrate; a memory storing mode which applies bias for improving stability to the transistor substrate; and a low leak mode which applies back bias to the transistor substrate, the substrate bias control unit performing transition between each of the modes according to an operation state of a circuit. In this case, an appropriate electric potential can be applied according to the operation state of the circuit so that it enables to achieve the high-speed operation, low electric consumption, and the stabilization.

Further, it is transited to the low leak mode except for the time of reading-out and writing operations. With this, it is possible to suppress the leak current of the memory cell except for the time of reading-out and writing operation.

Moreover, the substrate bias control unit performs transition between the high-speed writing mode, the high-speed reading-out mode, the memory storing mode and the low leak mode by predicting a circuit operation. In this case, the speed of applying the substrate potential can be increased so that it enables to achieve the high-speed transition between the writing mode, the reading-out mode, the memory storing mode and the low leak mode. Thus, the speed of the circuit operation can be increased.

Moreover, the substrate bias control unit performs the transition between each of the modes by detecting a state of special bit of cache memory. In this case, the transistor substrate potential of the memory cell can be so applied that the operation of the cache memory becomes appropriate according to the state of the special bit of the cache memory.

The special bit is a hit signal. In this case, the transistor substrate potential of the cache memory cell can be varied at the time of hit and the time of mishit of the cache. Thereby, the performance of the cache access can be improved.

Also, the special bit is a valid bit signal. In this case, the transistor substrate potential of the cache memory cell can be varied at the time when the cache data is valid and the time when it is invalid. Thereby, the performance of the cache access can be improved.

Further, the substrate bias control unit performs transition between each of the modes by detecting redundancy relief information held by a redundancy relief memory. In this case, the transistor substrate potential of the cache memory cell can be varied at the time when the redundancy is relieved and the time when it is unrelieved. Thereby, the leak current of the unused memory cell can be suppressed.

The present invention is not limited to only to the above-described embodiments but the various modifications are possible within the scope and the spirit of the appended claims.

Additional objects and advantages of the present invention will be apparent from the following detailed description of preferred embodiments thereof, which are best understood with reference to the accompanying drawings.

### BRIEF DESCRIPTION OF THE DRAWINGS

FIG. 1 is a block diagram of a semiconductor memory according to a first embodiment of the present invention;

FIG. 2 is a block diagram showing a half of a memory cell under the state where a word line is active;

FIG. 3 is an illustration showing input/output characteristics of an inverter inside the memory cell of FIG. 2 and the noise margin;

FIG. 4 is a block diagram of a semiconductor memory according to a second embodiment of the present invention;

FIG. 5 is a block diagram of a semiconductor memory according to a third embodiment of the present invention;

FIG. 6 is a block diagram of a semiconductor memory according to a fourth embodiment of the present invention;

FIG. 7 is a block diagram of a semiconductor memory according to a fifth embodiment of the present invention;

FIG. 8 is a block diagram in which a substrate of a memory cell array of the semiconductor memory according to the fifth embodiment of the present invention are separated by a column unit;

FIG. 9 is a block diagram of a semiconductor memory according to a sixth embodiment of the present invention; and

FIG. 10 is a block diagram of a semiconductor memory according to a sixth embodiment of the present invention.

In each illustration, same reference numerals are applied to the same components.

### DETAILED DESCRIPTION OF THE PREFERRED EMBODIMENTS

In the followings, embodiments of the present invention will be described by referring to the accompanying drawings.

(First Embodiment)

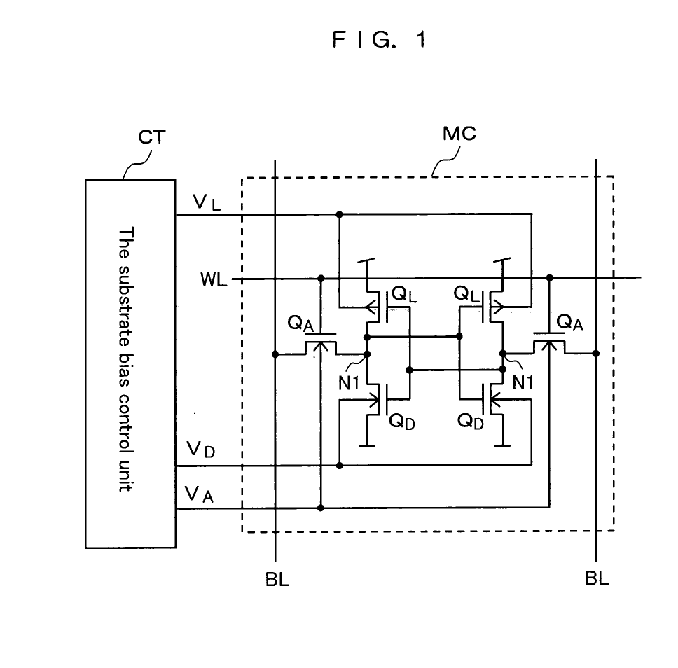

As shown in FIG. 1, a semiconductor memory according to a first embodiment comprises a static-type memory cell MC and a substrate bias control unit CT for applying bias onto a transistor substrate of the memory cell MC.

The memory cell MC is configured with a pair of access transistors Q_{A} formed with NMOS transistors, a pair of drive transistors Q_{D} formed with NMOS transistors, and a pair of load transistors Q_{L} formed with PMOS transistors. The pair of load transistors Q_{L} and the pair of drive transistors Q_{D} form a memory storage. The junction point between the load transistor Q_{L} and the drive transistor Q_{D} is a memory storage node N1 to which the access transistors Q_{A} is connected.

The substrate bias control unit CT increases the access speed at the time of making access to the memory cell MC by adjusting electric current flown to the memory storage node N1 of the memory cell MC. In the meantime, it applies bias for improving the stability of the memory storage node N1 at the time of non-access.

Reference numeral WL is a word line and is connected to gates of the access transistors Q_{A}. Reference numeral BL is a bit line and is connected to drains of the access transistors Q_{A}. The substrate bias control unit CT supplies substrate potential V_{L} to the load transistors Q_{L}, supplies substrate potential V_{D} to the drive transistors Q_{D}, and supplies substrate potential V_{A} to the access transistors Q_{A}. These substrate potentials V_{L}, V_{D}, V_{A} are supplied separately from each other.

The factors for determining the performance of the static-type memory are the writing speed, reading-out speed, the stability of the memory cell, etc. These depend on the performance of the load transistor, the drive transistor and the access transistor.

The smaller the current of the load transistor and the drive transistor is, the faster the writing speed becomes, and the larger the current of the access transistor is, the faster the writing speed becomes.

The larger the current of the access transistor and the drive transistor is, the faster the reading-out speed becomes.

The stability of the memory cell is expressed by an index called a static noise margin. The noise margin is defined as a maximum voltage of the noise by which data inside the memory cell is not destroyed at the time of reading-out. When this value is large, the data in the memory cell is not easily destroyed, which means it has a high stability. The noise is caused by asymmetrical layout, dispersions in the process, etc.

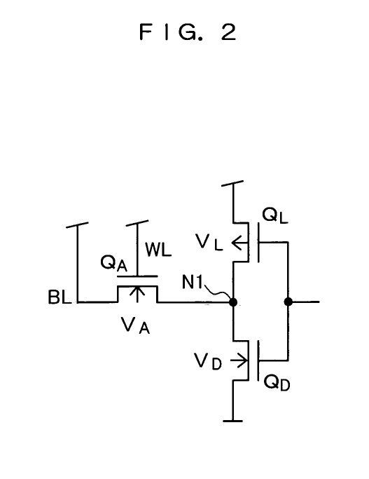

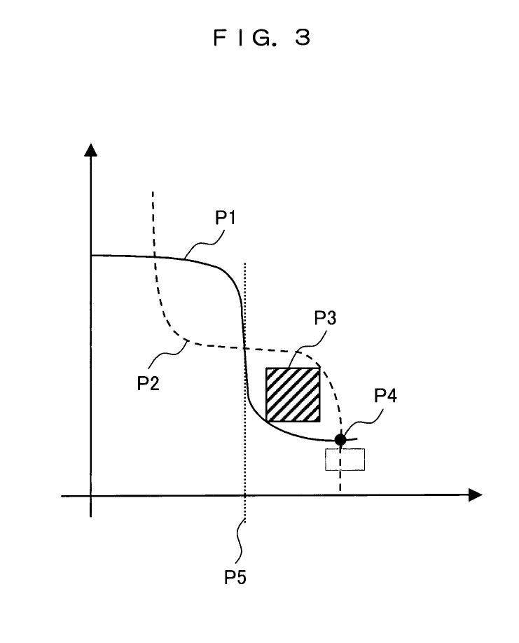

Now, the noise margin will be described. FIG. 2 shows a half of the memory cell under the state where the word line is active. FIG. 3 is an illustration showing the input/output characteristic of an inverter inside the memory cell of FIG. 2, in which the case (P1) with X-axis being input, Y-axis being output and the case (P2) with Y-axis being input, X-axis being output overlap with each other. In FIG. 3, one of the sides of a square P3 which is inscribed to input/output curves is the noise margin, and the larger the square P3 is, the more stable the memory cell becomes. In order to increase the noise margin, an electric potential P4 in FIG. 3 may be decreased by increasing the current ratio between the drive transistor and the access transistor. Also, an electric potential P5 in FIG. 3 may be increased by increasing the current ratio of the load transistor and the drive transistor. Or, slopes of the input/output waveforms P1, P2 at the time of switching may be made steeper by increasing the threshold voltage of the transistor.

At the time of writing, the following controls of the substrate potential are carried out for achieving the high-speed writing.

(1) Back bias is applied as the substrate potential V_{L} of the load transistor Q_{L}. Thereby, the current of the load transistor Q_{L} is decreased so that the capacity of holding the memory storage node N1 to the state before writing data is deteriorated. Thus, the speed of writing can be increased.

(2) Forward bias is applied as the substrate potential V_{A} of the access transistor Q_{A}. Thereby, the current of the access transistor is increased so that the capacity of writing data of the bit line BL to the memory storage node N1 is improved. Thus, the speed of writing can be increased.

(3) Back bias is applied as the substrate potential V_{D} of the drive transistor Q_{D}. Thereby, the current of the drive transistor Q_{L} is decreased so that the capacity of holding the memory storage node N1 to the state before writing data is deteriorated. Thus, the speed of writing can be increased.

(4) All or at least two out of above-described (1)-(3) are performed; (1) applying the back bias as the substrate potential V_{L} of the load transistor Q_{L}, (2) applying the forward bias as the substrate potential V_{L} of the load transistor Q_{L}, (3) applying the back bias as the substrate potential V_{D} of the drive transistor Q_{D}. Thereby, writing can be performed at a still higher speed by the same applied voltage as the case of applying the bias separately to the substrate potentials of the load transistor Q_{L}, the access transistor Q_{A}, and the drive transistor Q_{D}.

(5) Forward bias is applied as the substrate potentials V_{A}, V_{D} of the access transistor Q_{A} and the drive transistor Q_{D}. Thereby, the current of the access transistor and that of the drive transistor is increased so that the capacity of writing data of the bit line BL to the memory storage node N1 is improved and, at the same time, the capacity of holding the memory storage node N1 to the state before writing data is improved. Here, by setting the extent of the improvement in the capacity of writing data larger than the improvement of the capacity of holding the state of the memory storage node N1 to the state before writing data, the speed of writing can be increased. In this case, the noise margin becomes larger than the case where the forward bias is applied as the substrate potential V_{A} of the access transistor Q_{A} and the back bias is applied as the substrate potential V_{D} of the drive transistor Q_{D}, thereby improving the stability. Moreover, the same substrate potential can be applied by using a common substrate potential for the substrate potential V_{A} of the access transistor Q_{A} and the substrate potential V_{D} of the drive transistor Q_{D}. In this case, it is unnecessary to separate the substrate of the access transistor Q_{A} and that of the drive transistor Q_{D}. Thus, the area of the memory cell can be made small and the structure of the substrate bias control unit CT can be simplified as well.

(6) Back bias is applied as the substrate potential V_{L} of the load transistor Q_{L}, and forward bias is applied as the substrate potentials V_{A}, V_{D} of the access transistor Q_{A} and the drive transistor Q_{D}. Thereby, writing can be performed at a higher speed than the case where the forward bias is applied as the substrate potentials V_{A}, V_{D} of the access transistor Q_{A} and the drive transistor Q_{D}.

At the time of reading-out, the following controls of the substrate potential are carried out for achieving the high-speed writing.

(1) Forward bias is applied as the substrate potential V_{A} of the access transistor Q_{A}. Thereby, the current of the access transistor Q_{A} is increased so that the speed of reading-out can be increased.

(2) Forward bias is applied as the substrate potential V_{D} of the drive transistor Q_{D}. Thereby, the current of the drive transistor Q_{D} is increased so that the speed of reading-out can be increased.

(3) Forward bias is applied as the substrate potentials V_{A}, V_{D} of the access transistor Q_{A} and the drive transistor Q_{D}. Thereby, reading-out can be performed at a still higher speed by the same applied voltage as the case where the bias is applied separately to the substrate potentials V_{A}, V_{D} of the access transistor Q_{A} and the drive transistor Q_{D}. Moreover, the same substrate potential can be applied by using a common substrate potential for the substrate potential V_{A} of the access transistor Q_{A} and the substrate potential V_{D} of the drive transistor Q_{D}. In this case, it is unnecessary to separate the substrate of the access transistor Q_{A} and that of the drive transistor Q_{D}. Thus, the area of the memory cell can be made small and the structure of the substrate bias control unit CT can be simplified as well.

At the time of reading-out, the stability of the memory cell can be improved by performing the following controls of the substrate potential.

(1) Forward bias is applied as the substrate potential V_{L} of the load transistor Q_{L}. Thereby, the current of the load transistor Q_{L} is increased. Thus, the current ratio between the load transistor and the drive transistor becomes large so that the stability of the memory call can be improved.

(2) Back bias is applied as the substrate potential V_{A} of the access transistor Q_{A}. Thereby, the current of the access transistor Q_{A} is decreased. Thus, the current ratio between the drive transistor and the access transistor becomes large so that the stability of the memory call can be improved.

(3) Forward bias is applied as the substrate potential V_{D} of the drive transistor Q_{D}. Thereby, the current of the drive transistor Q_{D} is increased. Thus, the current ratio between the drive transistor and the access transistor becomes large so that the stability of the memory call can be improved.

(4) All or at least two out of the above-described (1)-(3) are performed; (1) applying the forward bias as the substrate potential V_{L} of the load transistor Q_{L}, (2) applying the back bias as the substrate potential V_{A} of the access transistor Q_{A}, (3) applying the forward bias as the substrate potential V_{D} of the drive transistor Q_{D}. Thereby, the stability of the memory cell can be further improved by the same applied voltage as the case of applying the bias separately to the substrate potentials of the load transistor Q_{L}, the access transistor Q_{A}, and the drive transistor Q_{D}.

(5) Back bias is applied as the substrate potentials V_{A}, V_{D} of the access transistor Q_{A} and the drive transistor Q_{D}. Thereby, the current of the access transistor and that of the drive transistor is decreased. Thus, the current ratio between the load transistor and the drive transistor becomes large and the stability of the memory cell can be improved. Moreover, the same substrate potential can be applied by using a common substrate potential for the substrate potential V_{A} of the access transistor Q_{A} and the substrate potential V_{D} of the drive transistor Q_{D}. In this case, it is unnecessary to separate the substrate of the access transistor Q_{A} and that of the drive transistor Q_{D}. Thus, the area of the memory cell can be made small and the structure of the substrate bias control unit CT can be simplified as well.

(6) Forward bias is applied as the substrate potential V_{L} of the load transistor Q_{L} and back bias is applied to the substrate potentials V_{A}, V_{D} of the access transistor Q_{A} and the drive transistor Q_{D}. Thereby, the stability of the memory cell can be more improved compared to the case where the back bias is applied to the substrate potentials V_{A}, V_{D} of the access transistor Q_{A} and the drive transistor Q_{D}.

In the static-type memory cell according to the embodiment of the present invention, the substrate potentials of the load transistor, the drive transistor and the access transistor can be controlled separately. Therefore, it is possible to increase the writing speed and the reading-out speed, and to stabilize the memory cell through a plurality of types of controls performed on the substrate potentials. Thus, an appropriate SRAM macrocode can be designed taking account of bias setting at a normal time and the simplicity of the substrate potential control at the time of allying the bias. For example, the standard bias and the size of the memory cell transistor are so set that the speed of writing and reading-out to/from the memory cell can be performed at a high speed, and the bias is applied to the memory cell which stores data for improving the stability. Inversely, the normal bias and the size of the memory cell transistor are so set that the stability of the memory cell can be increased, and the bias is applied to the memory cell which is accessed at the time of writing and reading-out for increasing the speed. Moreover, it is possible, by considering the speed, the stability, the layout area, the control circuit area, the simplicity of the control, etc., to set the bias application in such a manner that the bias is applied only to the load transistor, applied to both the access transistor and the drive transistor, applied to all the transistors.

(Second Embodiment)

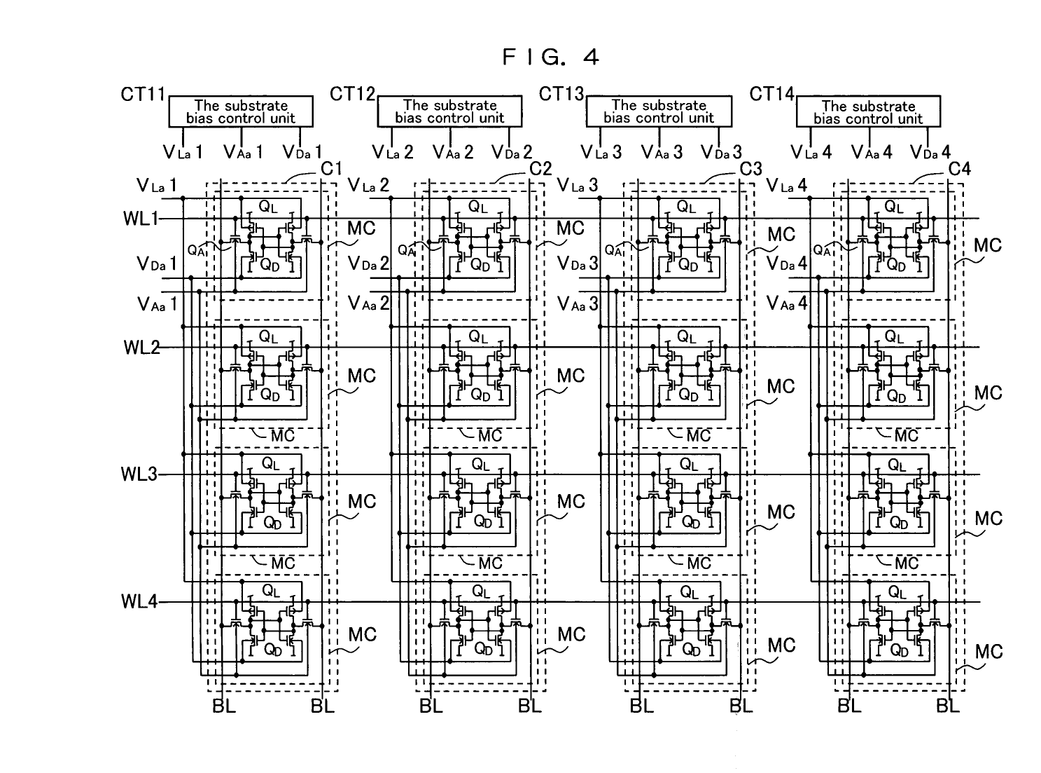

A semiconductor memory according to a second embodiment of the present invention will be described by referring to FIG. 4. Shown in the illustration is an example of a SRAM memory cell array with four columns, four rows, and 1 bit output. In FIG. 4, reference numerals C1, C2, C3, C4 are the columns. Reference numerals W1, W2, W3, W4 are word lines being connected to the gates of the access transistor Q_{A} of each column. Reference numeral BL is a bit line being connected to the drains of the access transistors Q of each row. Reference numerals V_{La}1, V_{La}2, V_{La}3, V_{La}4 are the substrate potentials of the load transistors Q_{L} of each column, V_{Da}1, V_{Da}2, V_{Da}3, V_{Da}4 are the substrate potentials of the drive transistors Q_{D} of each column, and V_{Aa}1, V_{Aa}2, V_{Aa}3, V_{Aa}4 are the substrate potentials of the access transistors Q_{A} of each column. The same substrate potential is applied to the transistors of the memory cell in the same column. The substrate potential is separately applied to the transistors of the memory cell in different columns. Reference numerals CT11, CT12, CT13, CT14 are the substrate bias control units of each column.

With this configuration, it is possible to apply separate substrate potential to the transistor of a selected column including the memory cell to be accessed and to the transistor of unselected column formed with the memory cell which is not to be accessed.

At the time of writing, the control for achieving the high-speedwriting according to the first embodiment is performed on the substrate potential of the selected column. At the time of reading-out, the control for achieving the high-speed reading-out according to the first embodiment is performed on the substrate potential of the selected column. Thereby, the speed of making access to the memory for writing and reading-out can be improved.

Further, since the control of the substrate potential can be performed by each column, the substrate capacitance to be controlled becomes small so that it enables to achieve high-speed control. Also, in the unselected columns, performed is the substrate potential control for improving the stability of the memory cell according to the first embodiment. Thereby, it is possible to improve the stability of the memory cell which is not to be accessed. Further, the back bias is applied to the substrate potentials of the unselected columns. Thereby, leak current of the memory cell not to be accessed can be decreased.

The substrate potential of the selected column and that of the unselected columns can be individually controlled so that the controls can be performed in combinations, e.g. the writing speed is increased in the selected column and the state is stabilized in the unselected column; the writing speed is increased in the selected column and the leak current is decreased in the unselected column; the reading-out speed is increased in the selected column and the state is stabilized in the unselected column; or the reading-out speed is increased in the selected column and the leak current is decreased in the unselected column.

In general, for the memory cells with columns, to which the selected word line is connected, an apparent reading-out operation is also performed on the memory cells of the unselected columns. When the substrate potential control according to the first embodiment for achieving the high-speed writing is performed on the entire memory cell in order to achieve high-speed writing, the stability of the memory cell of the unselected column is decreased. Since the stability of the memory cell of the unselected column is deteriorated, the substrate potential controls for achieving the high-speed writing can be performed only to the extent where there is no malfunction (destruction of the data in the memory cell) being caused.

However, with the configuration according to the second embodiment of the present invention, the high stability of the memory cell of the unselected column can also be achieved even when the high-speed writing is performed. Therefore, there is no malfunction being caused even if the substrate potential control for achieving the high-speed writing is performed on the selected column to the extent where the data of the memory cell is destructed, so that the effect of achieving high-speed can be improved.

(Third Embodiment)

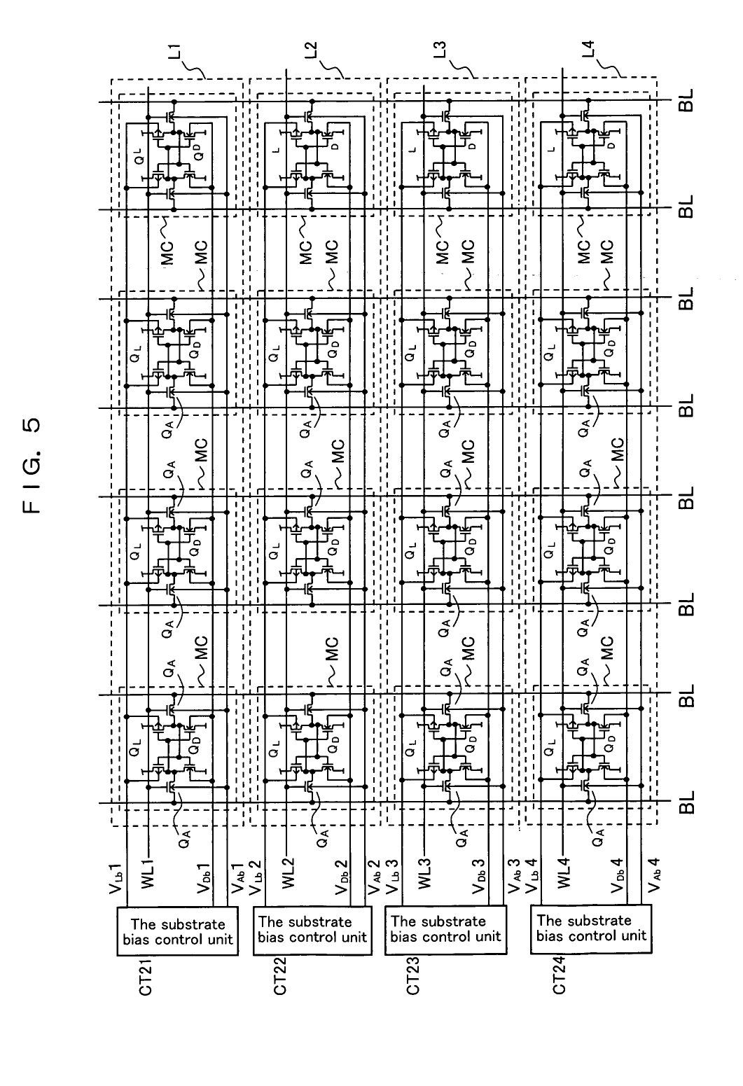

A semiconductor according to a third embodiment of the present invention will be described by referring to FIG. 5. In FIG. 5, the same reference numerals as those of the second embodiment in FIG. 2 denote the same structural elements so that detailed description is omitted. Reference numerals L1, L2, L3, L4 are rows. Reference numerals V_{Lb}1, V_{Lb}2, V_{Lb}3, V_{Lb}4 are the substrate potentials of the load transistors Q_{L}, V_{Db}1, V_{Db}2, V_{Db}3, V_{Db}4 are the substrate potentials of the drive transistors Q_{D}, and V_{Ab}1, V_{Ab}2, V_{Ab}3, V_{Ab}4 are the substrate potentials of the access transistors Q_{A}. The same substrate potentials are applied to the transistors of the memory cell in the same column. The substrate potentials are separately applied to the transistors of the memory cell in different columns. Reference numerals CT21, CT22, CT23, CT24 are the substrate bias control units of each column.

With this configuration, it is possible to apply separate substrate potential to the memory cell transistor of a selected row including the memory cell to be accessed and to the memory cell transistor of unselected row formed with the memory cell which is not to be accessed.

At the time of writing, the control for achieving the high-speedwriting according to the first embodiment is performed on the substrate potential of the selected row. At the time of reading-out, the control for achieving the high-speed reading-out according to the first embodiment is performed on the substrate potential of the selected row. Thereby, the speed of making access to the memory for writing and reading-out can be improved.

Further, since the control of the substrate potential can be performed by a row unit, the substrate capacitance to be controlled becomes small so that it enables to achieve high-speed control. Further, the back bias is applied to the substrate potentials of the unselected rows. Thereby, leak current of the memory cell which is not to be accessed can be decreased.

The transistor substrate of the selected row and that of the unselected rows can be individually controlled so that the controls can be performed in combinations, e.g. the writing speed is increased in the selected row and the leak current is decreased in the unselected rows; or the reading-out speed is increased in the selected row and the leak current is decreased in the unselected rows.

In general, in the memory cell with rows, if a large amount of leak current is flown to the access transistors of the unselected memory cell which is connected to the selected bit line, the electric potential of the bit line is deteriorated due to the leak current. Thus, the reading-out speed becomes slow and, in the worst case, there may generate an error in the read-out data.

However, with the third embodiment of the present invention, it is possible to decrease the leak current in the unselected memory cell by applying back bias as the substrate potential of the unselected row. Thus, it enables to avoid such problems.

(Fourth Embodiment)

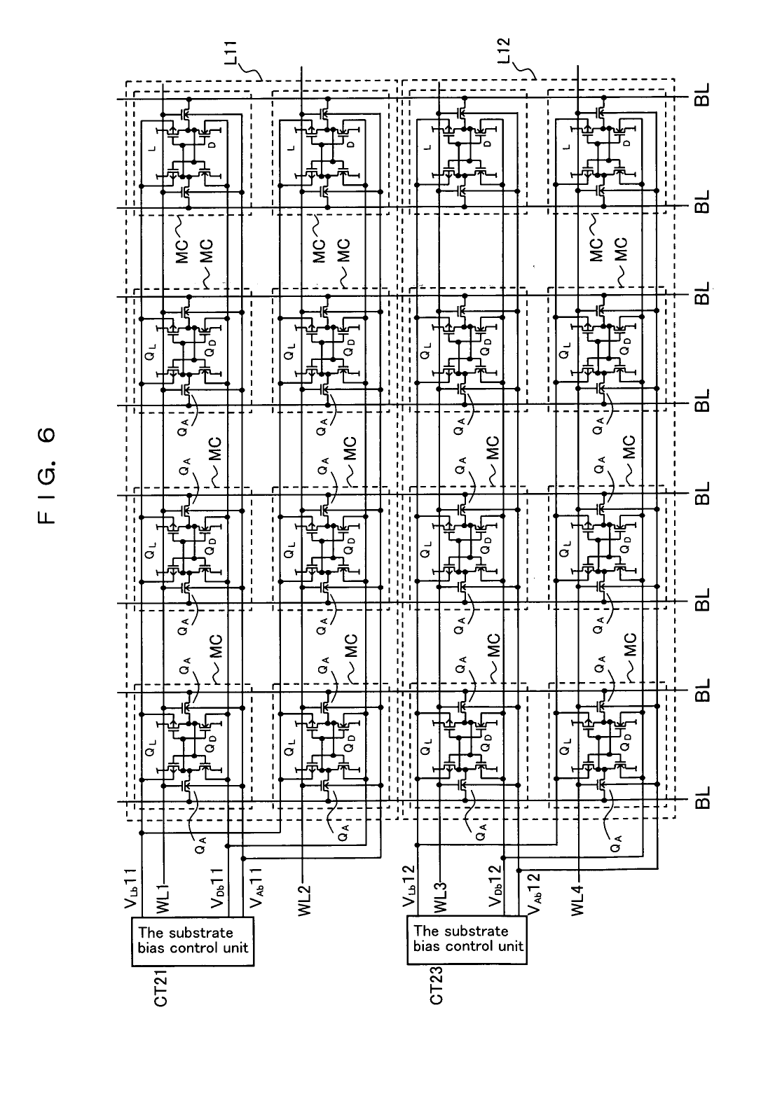

A semiconductor according to a fourth embodiment of the present invention will be described by referring to FIG. 6. The substrate potentials V_{Lb}1 and V_{Lb}2 of the load transistor of the third embodiment in FIG. 5 are put together as V_{Lb}11, V_{Lb}3 and V_{Lb}4 are put together as V_{Lb}12, and the substrate potentials V_{Db}1 and V_{Db}2 of the drive transistor are put together as V_{Db}11, V_{Db}3 and V_{Db}4 to V_{Db}12, and the substrate potentials V_{Ab}1 and V_{Ab}2 of the access transistor are put together as V_{Ab}11, V_{Ab}3 and V_{Ab}4 are put together as V_{Ab}12. That is, the substrates of the memory cell transistors are controlled by being divided into L11 and L12 by every two rows.

With the configuration, by performing the same controls as those of the third embodiment by each substrate being divided by every two rows, the same effect can be achieved.

In the case where the substrate of the memory cell transistor is divided by a row unit, it is necessary to detect whether it is a selected row or unselected row according to a decoding result of the row address and control the substrate potentials of the memory cell transistor. However, by dividing the substrate of the memory cell transistor by a pre-decode unit, it is possible to detect whether or not it is a substrate including the selected row or a substrate with only the unselected row for controlling the substrate potential of the memory cell transistor. Thus, it enables to perform the substrate potential controls quickly.

In this embodiment, the substrate of the memory cell transistor is divided in the row direction. However, in addition, the substrate may be divided in the column direction and the substrate potential control may be performed by a memory cell unit.

(Fifth Embodiment)

As described above, by controlling the substrate potentials of the memory cell transistors, it enables to achieve the high-speed writing, the high-speed reading-out, stabilization of the memory cells, and reduction of the leak current. Further, by separating the transistor substrate of the memory cell in the column direction and the row direction, it enables to achieve the high-speed writing and high-speed reading-out to/from the memory cell to be accessed, while enabling to stabilize the memory cell which is not to be accessed and to reduce the leak current thereof. In the actual operation of the semiconductor memory, writing operation, reading-out operation and non-access operation are randomly generated so that the required effects vary accordingly.

By providing a high-speed writing mode, a high-speed reading-out mode, a memory storing mode, and a low leak mode, and transiting each operation mode according to the operation state of the circuit, it is possible to achieve the effects of increasing the speed of writing and reading-out, stabilizing the memory cells, and reducing the leak according to the operation state of the semiconductor memory. Moreover, in general, a change in the substrate potential by applying the substrate potential is slower than the circuit operation, so that it takes a long time to change the substrate potential after the operation mode is changed.

Thus, through transiting the operation mode by predicting the circuit operation beforehand, the speed of transiting the operation mode can be improved.

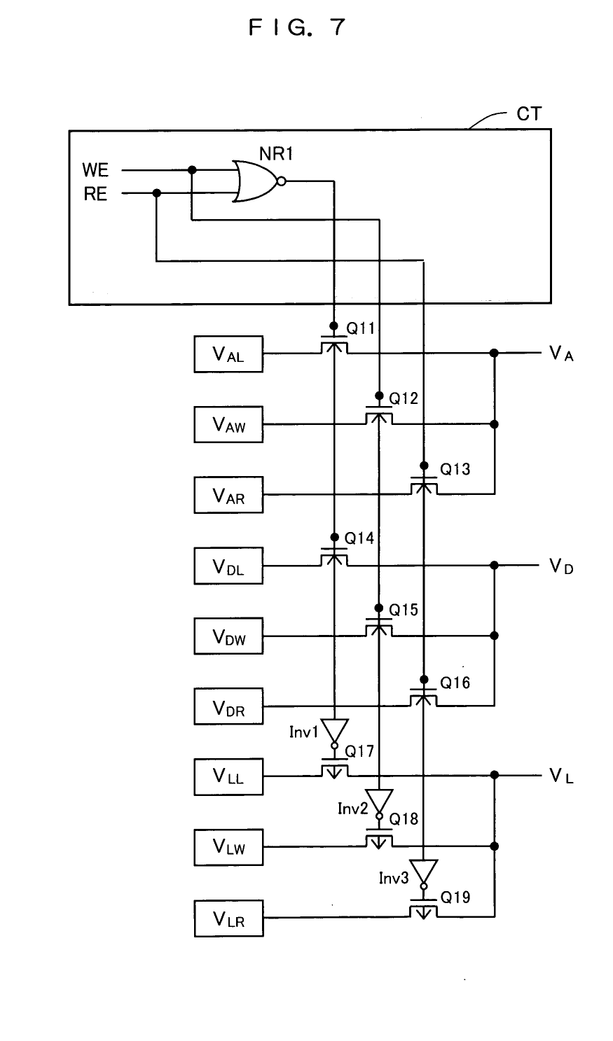

FIG. 7 shows an example of a semiconductor memory according to a fifth embodiment of the present invention. This is the case where the operation mode is transited to high-speed writing mode at the time of writing, to the high-speed reading-out mode at the time of reading-out, and to the low leak mode at the time of non-access. Reference numeral WE is a writing control signal and RE is a reading-out control signal. The writing control signal WE and the reading-out control signal RE are inputted to a NOR gate NR1. The output of the NOR gate NR1 is connected to gates of the transistors Q11, Q14 and is connected to a gate of a transistor Q17 through an inverter Inv1. The writing control signal WE is connected to gates of transistors Q12, Q15 and is connected to a gate of a transistor Q18 through an inverter Inv2. The reading-out control signal RE is connected to gates of transistors Q13, Q16 and is connected to a gate of a transistor Q19 through an inverter Inv3.

The transistor Q11 switches a substrate potential V_{AO} of the access transistor in the low leak mode, the transistor Q12 switches a substrate potential V_{AW} of the access transistor in the high-speed writing mode, and the transistor Q13 switches a substrate potential V_{AR} of the access transistor in the high-speed reading-out mode. As a result of the switching, a substrate potential V_{A} of the access transistor of the memory cell can be obtained.

The transistor Q14 switches a substrate potential V_{DO} of the drive transistor in the low leak mode, the transistor Q15 switches a substrate potential V_{DW} of the drive transistor in the high-speed writing mode, and the transistor Q16 switches a substrate potential V_{DR} of the drive transistor in the high-speed reading-out mode. As a result of the switching, a substrate potential V_{D} of the drive transistor of the memory cell can be obtained.

The transistor Q17 switches a substrate potential V_{LO} of the load transistor in the low leak mode, the transistor Q18 switches a substrate potential V_{LW} of the load transistor in the high-speed writing mode, and the transistor Q19 switches a substrate potential V_{LR} of the load transistor in the high-speed reading-out mode. As a result of the switching, a substrate potential V_{L} of the access transistor of the memory cell can be obtained.

The substrate potential V_{AO} of the access transistor, the substrate potential V_{DO} of the drive transistor and the substrate potential V_{LO} of the load transistor in the low leak mode are respectively set to be in the potential for applying back bias to the respective transistors.

The substrate potential V_{AW} of the access transistor, the substrate potential V_{DW} of the drive transistor and the substrate potential V_{LW} of the load transistor in the high-speed writing mode are so set that bias for increasing the writing speed as described above is applied to the respective transistors.

The substrate potential V_{AR} of the access transistor, the substrate potential V_{DR} of the drive transistor and the substrate potential V_{LR} of the load transistor in the high-speed reading-out mode are so set that bias for increasing the reading-out speed as described above is applied to the respective transistors.

With the configuration, when the writing control signal WE and the reading-out control signal RE are unselected, that is, in the non-access state, all the substrate potentials V_{AO}, V_{DO}, V_{LO} in the low leak mode are supplied to the substrates of each of the access, drive, load transistors and the low-leak operation is performed. When the writing control signal WE is selected and the reading-out control signal RE is unselected, that is, when writing, all the substrate potentials V_{AW}, V_{DW}, V_{LW} in the high-speed writing mode are supplied to the substrates of each of the access, drive, load transistors and the high-speed writing is performed. When the writing control signal WE is unselected and the reading-out control RE signal is selected, that is, when reading-out, all the substrate potentials V_{AR}, V_{DR}, V_{LR} in the high-speed reading-out mode are supplied to the substrates of each of the access, drive, load transistors and the high-speed reading-out is performed. Thereby, it is possible to achieve an appropriate effect by corresponding to the respective operation state of the semiconductor memory.

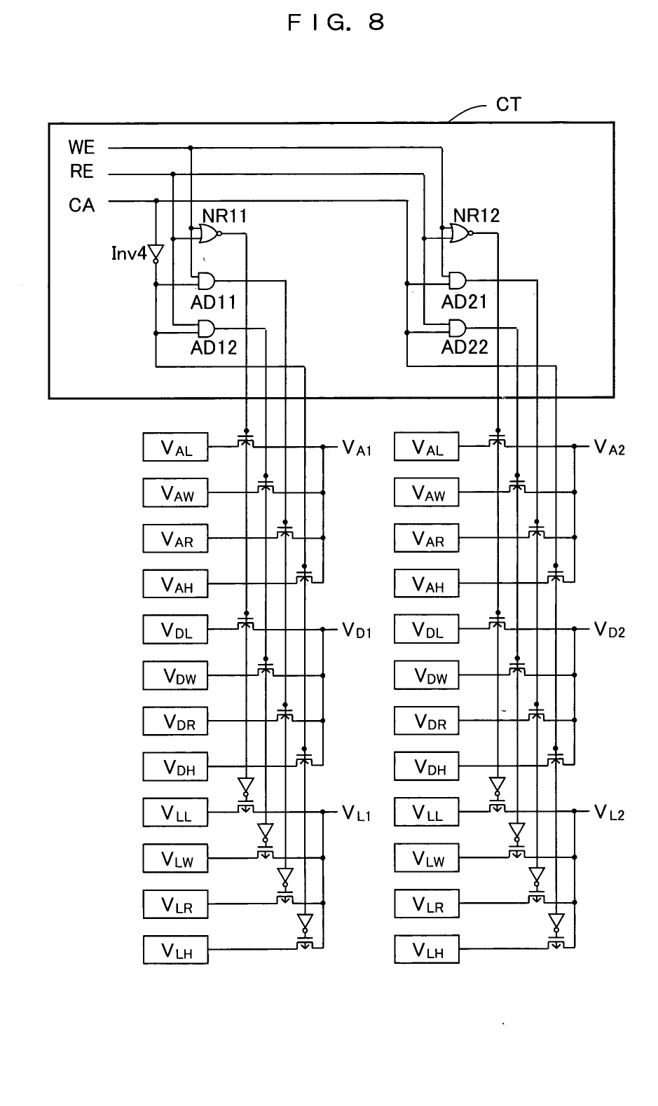

FIG. 8 shows an example of the bias control unit CT of the transistor substrate of the memory cell in a semiconductor memory with two-column structure, in the case where the transistor substrate of the memory cell is separated by a column unit, and the operation mode is transited to the high-speed writing mode at the time of writing data to the selected column, to the high-speed reading-out mode at the time of reading out data from the selected column, to the memory storing mode at the time of writing and reading-out data to/form the unselected column, and to the low leak mode at the time of non-access.

The substrate bias control unit CT comprises NOR gates NR11, NR12, AND gates AD11, AD12, AD21, AD22, and an inverter Inv4, which are connected as show in the figure. Reference numeral WE is a writing control signal and RE is a reading-out signal. Reference numeral CA is a column address and when it is “0”, the column 1 is accessed and, when it is “1”, the column 2 is accessed. Reference numeral V_{AL} is a substrate potential of the access transistor in the low leak mode, V_{AW} is a substrate potential of the access transistor in the high-speed writing mode, V_{AR} is a substrate of the access transistor in the high-speed reading-out mode, and V_{AH} is a substrate potential of the access transistor in the memory storing mode. Reference numeral V_{A1} is connected to the substrate potential of the access transistor in column 1 of the semiconductor memory, V_{A2} is connected to the substrate potential of the access transistor in column 2 of the semiconductor memory. Reference numeral V_{DL} is a substrate potential of the drive transistor in the low leak mode, V_{DW} is a substrate potential of the drive transistor in the high-speed writing mode, V_{DR} is a substrate of the drive transistor in the high-speed reading-out mode, and V_{DH} is a substrate potential of the drive transistor in the memory storing mode. Reference numeral V_{D1} is connected to the substrate potential of the drive transistor in column 1 of the semiconductor memory, V_{D2} is connected to the substrate potential of the drive transistor in column 2 of the semiconductor memory. Reference numeral V_{LL} is a substrate potential of the load transistor in the low leak mode, V_{LW} is a substrate potential of the load transistor in the high-speed writing mode, V_{LR} is a substrate of the load transistor in the high-speed reading-out mode, and V_{LH} is a substrate potential of the load transistor in the memory storing mode. Reference numeral V_{L1} is connected to the substrate potential of the load transistor in column 1 of the semiconductor memory, V_{L2} is connected to the substrate potential of the load transistor in column 2 of the semiconductor memory.

The substrate potential V_{AO} of the access transistor in the low leak mode, the substrate potential V_{DO} of the drive transistor in the low leak mode and the substrate potential V_{LO} of the load transistor in the low leak mode are respectively set to be in the electric potential for applying back bias to the respective transistors.

The substrate potential V_{AW} of the access transistor in the high-speed writing mode, the substrate potential V_{DW} of the drive transistor in the high-speed writing mode and the substrate potential V_{LW} of the load transistor in the high-speed writing mode are so set that the bias for increasing the writing speed as described above is applied to the respective transistors.

The substrate potential V_{AR} of the access transistor in the high-speed reading-out mode, the substrate potential V_{DR} of the drive transistor in the high-speed reading-out mode and the substrate potential V_{LR} of the load transistor in the high-speed reading-out mode are so set that the bias for increasing the reading-out speed as described above is applied to the respective transistors.

The substrate potential V_{AH} of the access transistor in the data retention mode, the substrate potential V_{DH} of the drive transistor in the data retention mode and the substrate potential V_{LH} of the load transistor in the data retention mode are so set that the bias for increasing the stability as described above is applied to the respective transistors.

With this configuration, when the writing control signal WE and the reading-out control signal RE are unselected, that is, in the non-access state, all the substrate potentials V_{AL}, V_{DL}, V_{LL} in the low leak mode are supplied to the substrates of each of the access, drive, and load transistors, so that the low leak operation is performed.

When the writing control signal WE is selected and the reading-out control signal RE is unselected, that is when writing, all the substrate potentials V_{AW}, V_{DW}, V_{LW} in the high-speedwriting mode are supplied to the substrates of each of the access, drive, load transistors of the selected column so that the high-speed writing is performed on the selected column, while all the substrate potentials V_{AH}, V_{DH}, V_{LH} in the memory storing mode are supplied to the substrates of each of the access, drive, load transistors of the unselected column so that the stability of the memory cell in the unselected column is improved.

When the writing control signal WE is unselected and the reading-out control signal RE is selected, that is, when reading out, all the substrate potentials V_{AR}, V_{DR}, V_{LR} in the high-speed reading-out mode are supplied to the substrates of each of the access, drive, load transistors of the selected column so that the high-speed reading-out is performed on the selected column, while all the substrate potentials V_{AH}, V_{DH}, V_{LH} in the memory storing mode are supplied to the substrates of each of the access, drive, load transistors of the unselected column so that the stability of the memory cell in the unselected column is improved. Therefore, it enables to achieve an appropriate effect by corresponding to the respective operation state of the semiconductor memory.

The aforementioned example is the case where the transistor substrate of the memory cell is separated by a column unit in two-column structure. In the case where the transistor substrate of the memory cell is separated by the plural-column structure, the substrate bias control unit may be formed in the same manner by using the decoded result of the column address instead of using the column address. In the case where the transistor substrate of the memory cell is separated by a row unit, the substrate bias control unit may be formed in the same manner by using the row address instead of using the column address. In the case where the transistor substrate of the memory cell is separated by a unit of the plural columns or the plural rows, the substrate bias control unit may be formed in the same manner by using the decoded result which can identify the separated block.

(Sixth Embodiment)

In general, there is a special bit in cache memory and the operation of the cache memory depends on the bits. For example, based on a hit signal as a result of a comparison between a TAG address and an address in a TAG memory, cache data is read out from the cache data memory when it is hit, and the reading-out of cache data from the cache data memory is stopped when it is mishit. Moreover, valid bit has information on whether or not the data stored in the cache data memory is valid or invalid.

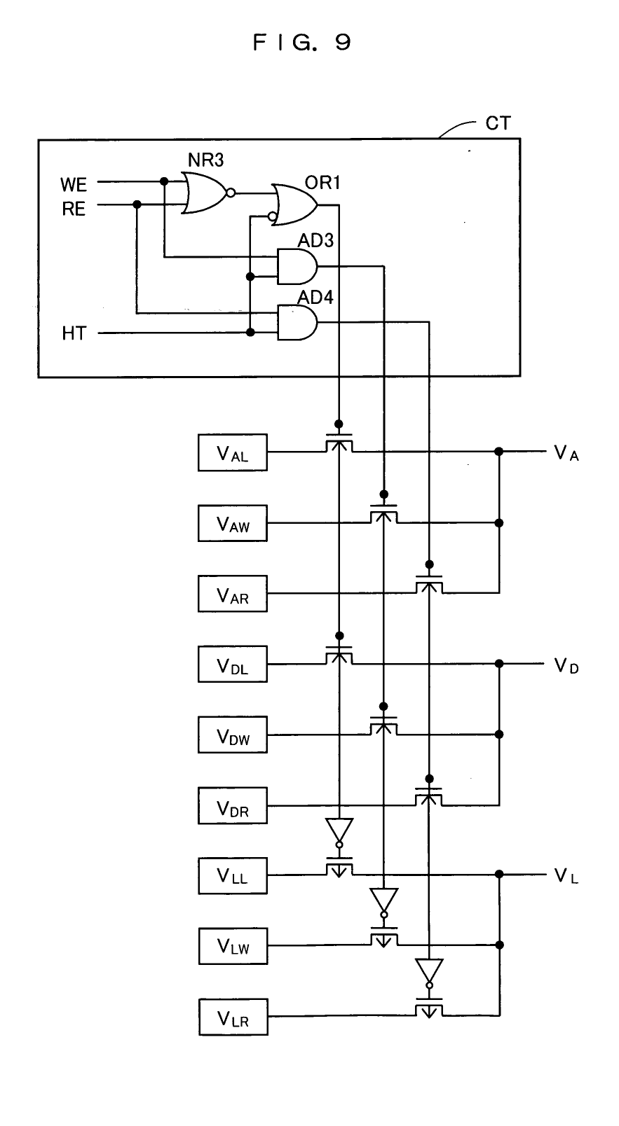

FIG. 9 is an example of a semiconductor memory according to a sixth embodiment of the present invention. This example shows the case where, according to the hit signal, the operation mode is transited to the high-speed writing mode for writing and to the high-speed reading-out mode for reading out when it is hit, and transited to the low leak mode when it is mishit.

The substrate bias control unit CT comprises a NOR gate NR3, an OR gate OR1, AND gates AD3, AD4, which are connected as shown in the figure. Reference numeral WE is a writing control signal, RE is a reading-out control signal, HT is a hit signal form the TAG memory, and “1” means hit and “0” means mishit. Reference numeral V_{AL} is a substrate potential of the access transistor in the low leak mode, V_{AW} is a substrate potential of the access transistor in the high-speed writing mode, V_{AR} is a substrate potential of the access transistor in the high-speed reading-out mode, and V_{A} is connected to the substrate potential of the access transistor of the semiconductor memory. Reference numeral V_{DL} is a substrate potential of the drive transistor in the low leak mode, V_{DW} is a substrate potential of the drive transistor in the high-speed writing mode, V_{DR} is a substrate of the drive transistor in the high-speed reading-out mode, and V_{D} is connected to the substrate potential of the drive transistor of the semiconductor memory. Reference numeral V_{LL} is a substrate potential of the load transistor in the low leak mode, V_{LW} is a substrate potential of the load transistor in the high-speed writing mode, V_{LR} is a substrate of the load transistor in the high-speed reading-out mode, and V_{L} is connected to the substrate potential of the load transistor of the semiconductor memory. The substrate potential V_{AW} of the access transistor in the high-speed writing mode, the substrate potential V_{DW} of the drive transistor in the high-speed writing mode and the substrate potential V_{LW} of the load transistor in the high-speed writing mode are so set that the bias for increasing the writing speed as described above is applied to the respective transistors. The substrate potential V_{AR} of the access transistor in the high-speed reading-out mode, the substrate potential V_{DR} of the drive transistor in the high-speed reading-out mode and the substrate potential V_{LR} of the load transistor in the high-speed reading-out mode are so set that the bias for increasing the reading-out speed as described above is applied to the respective transistors.

With this configuration, when the hit signal HT from the TAG memory is “0”, that is, when the cache is mishit, all the substrate potentials V_{AL}, V_{DL}, V_{LL} in the low leak mode are supplied to the substrates of each of the access, drive, load transistors, so that the low leak operation is performed. When the hit signal HT form the TAG memory is “1”, that is when the cache is hit, the following operations are performed.

When the writing control signal WE is selected and the reading-out control signal RE is unselected, that is when writing, all the substrate potentials V_{AW}, V_{DW}, V_{LW} in the high-speed writing mode are supplied to the substrates of each of the access, drive, load transistors so that the high-speed writing is performed.

When the writing control signal WE is unselected and the reading-out control signal RE is selected, that is, when reading out, all the substrate potentials V_{AR}, V_{DR}, V_{LR} in the high-speed reading-out mode are supplied to the substrates of each of the access, drive, load transistors so that the high-speed reading-out is performed.

Thereby, it enables to achieve an appropriate effect by corresponding to the respective operation state of the semiconductor memory.

This embodiment has been described by referring to the case where the hit signal is the special bit. However, with the valid bit, the same effect can be achieved by the same configuration. That is, the operation is performed in the low leak mode when the data is invalid, and an appropriate effect can be achieved by corresponding to the respective operation state when the data is valid.

(Seventh Embodiment)

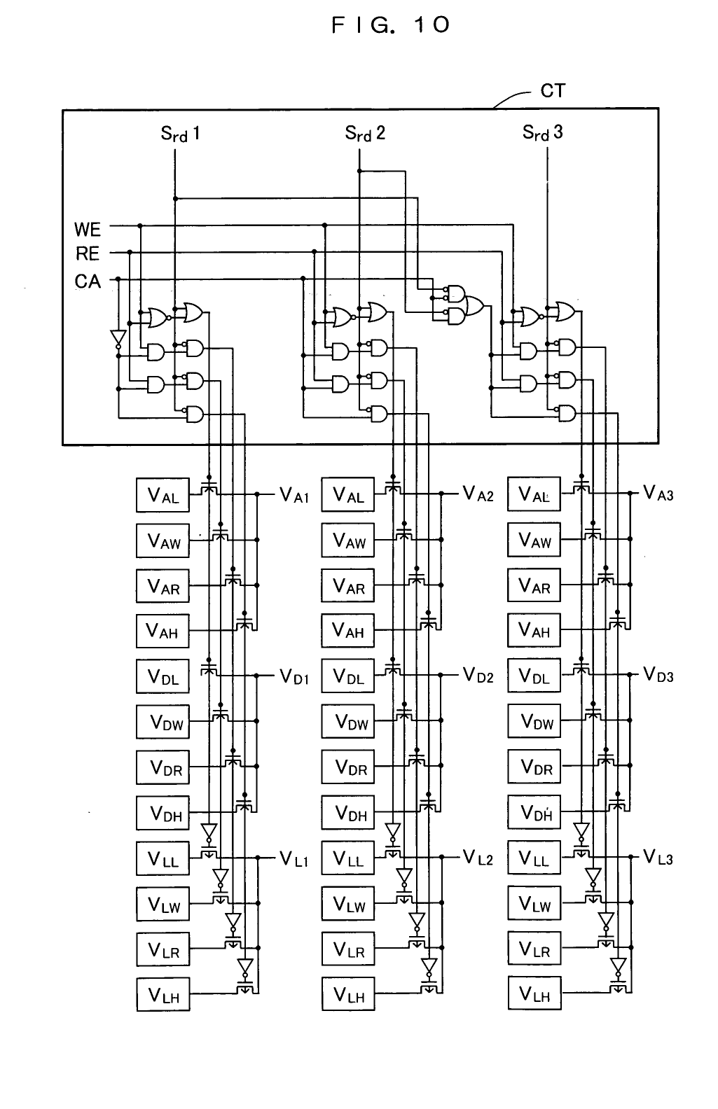

FIG. 10 is an example of a semiconductor memory according to a seventh embodiment of the present invention. FIG. 10 shows an example of the bias control unit CT of the transistor substrate of the memory cell in a semiconductor memory with redundancy relief, which is capable of replacing a defective column with a redundant column, in the case where the transistor substrate of the memory cell is separated by a column unit in a two-column structure, and the operation mode is transited to the high-speed writing mode when writing data to the selected column, to the high-speed reading-out mode when reading-out data from the selected column, to the memory storing mode when writing and reading-out data to/form the unselected column, and to the low leak mode at the time of non-access.

The substrate bias control unit CT comprises the above-described NOR gates, AND gates, inverter, OR gates, AND gates with inverse input, etc. which are connected as shown in the figure. Reference numeral WE is a writing control signal and RE is a reading-out control signal. Reference numeral CA is a column address, and when the address is “0”, the column 1 is accessed and when it is “1”, the column 2 is accessed. Reference numeral V_{AL} is a substrate potential of the access transistor in the low leak mode, V_{AW} is a substrate potential of the access transistor in the high-speed writing mode, V_{AR} is a substrate of the access transistor in the high-speed reading-out mode, and V_{AH} is a substrate potential of the access transistor in the memory storing mode. Reference numeral V_{A1} is connected to the substrate potential of the access transistor in column 1 of the semiconductor memory, V_{A2} is connected to the substrate potential of the access transistor in column 2 of the semiconductor memory, and V_{A3} is connected to the substrate potential of the access transistor in a redundant column of the semiconductor memory. Reference numeral V_{DL} is a substrate potential of the drive transistor in the low leak mode, V_{DW} is a substrate potential of the drive transistor in the high-speed writing mode, V_{DR} is a substrate of the drive transistor in the high-speed reading-out mode, and V_{DH} is a substrate potential of the drive transistor in the memory storing mode. Reference numeral V_{D1} is connected to the substrate potential of the drive transistor in column 1 of the semiconductor memory, V_{D2} is connected to the substrate potential of the drive transistor in column 2 of the semiconductor memory, and V_{D3} is connected to the substrate potential of the drive transistor in a redundant column of the semiconductor memory. Reference numeral V_{LL} is a substrate potential of the load transistor in the low leak mode, V_{LW} is a substrate potential of the load transistor in the high-speed writing mode, V_{LR} is a substrate of the load transistor in the high-speed reading-out mode, and V_{LH} is a substrate potential of the load transistor in the memory storing mode. Reference numeral V_{L1} is connected to the substrate potential of the load transistor in column 1 of the semiconductor memory, V_{L2} is connected to the substrate potential of the load transistor in column 2 of the semiconductor memory, and V_{L3} is connected to the substrate potential of the load transistor in a redundant column of the semiconductor memory.

The substrate potential V_{AL} of the access transistor in the low leak mode, the substrate potential V_{DL} of the drive transistor in the low leak mode and the substrate potential V_{LL} of the load transistor in the low leak mode are respectively set to be in the potential for applying back bias to the respective transistors.

The substrate potential V_{AW} of the access transistor in the high-speed writing mode, the substrate potential V_{DW} of the drive transistor in the high-speedwriting mode and the substrate potential V_{LW} of the load transistor in the high-speed writing mode are so set that bias for increasing the writing speed as described above is applied to the respective transistors. The substrate potential V_{AR} of the access transistor in the high-speed reading-out mode, the substrate potential V_{DR} of the drive transistor in the high-speed reading-out mode and the substrate potential V_{LR} of the load transistor in the high-speed reading-out mode are so set that bias for increasing the reading-out speed as described above is applied to the respective transistors. The substrate potential V_{AH} of the access transistor in the memory storing mode, the substrate potential V_{DH} of the drive transistor in the memory storing mode and the substrate potential V_{LH} of the load transistor in the memory storing mode are so set that bias for increasing the stability as described above is applied to the respective transistors.

Reference numeral S_{rd}1 is redundancy relief information stored in a fuse or a nonvolatile memory, which becomes “1” when there is a failure in the column 1 and becomes “0” when there is no failure; S_{rd}2 is redundancy relief information stored in a fuse or a nonvolatile memory, which becomes “1” when there is a failure in the column 2 and becomes “0” when there is no failure; and S_{rd}3 is redundancy relief information stored in a fuse or a nonvolatile memory, which becomes “1” when redundancy relief is performed and becomes “0” when no redundancy relief is performed.

With this configuration, when the redundancy relief information S_{rd}3 is “0”, that is, when no redundancy relief is carried out, all the substrate potentials V_{AL}, V_{DL}, V_{L} in the low leak mode are supplied to the substrates of each of the access, drive, load transistors of the memory cell in the redundant column, so that the low leak operation is performed regularly. At this time, as described in the fifth embodiment of the present invention in FIG. 8, as for the column 1 and the column 2, it is possible to achieve an appropriate effect by corresponding to the respective operation state.

When the redundancy relief information S_{rd}1 is “1”, that is, when there is a failure in the column 1 and it is replaced with the redundant column for carrying out redundancy relief, all the substrate potentials V_{AL}, V_{DL}, V_{LL} in the low leak mode are supplied to the substrates of each of the access, drive, load transistors of the memory cell in the column 1, so that the low leak operation is performed regularly. At this time, as described in the fifth embodiment of the present invention in FIG. 8, as for the column 2 and the redundant column, an appropriate effect can be achieved by corresponding to the respective operation state.

When the redundancy relief information S_{rd}2 is “1”, that is, when there is a failure in the column 2 and it is replaced with the redundant column for carrying out redundancy relief, all the substrate potentials V_{AL}, V_{DL}, V_{LL} in the low leak mode are supplied to the substrates of each of the access, drive, load transistors of the memory cell in the column 2, so that the low leak operation is performed regularly. At this time, as described in the fifth embodiment of the present invention in FIG. 8, as for the column 1 and the redundant column, an appropriate effect can be achieved by corresponding to the respective operation state.

This embodiment has been described by referring to the case where redundany relief is performed by replacing the column. However, it is possible to obtain the same effect as well in the case where the redundancy relief is performed by replacing the row through the same control by separating the transistor substrate of the memory cell by a row unit and providing a redundant row. Furthermore, when the substrate is separated in two or more of plural numbers in the row direction or separated in tow or more of plural numbers in the column direction, the same effect can be obtained by the same controls. In the case where the redundant block such as the redundant column and redundant row is not formed with the memory cell alone and that, for example, the redundant row including the row decoder is replaced, or the I/O circuit and the column decoder in addition to the redundant column are replaced, the row decoder and the substrate of the I/O circuit may be also separated and the same substrate potential control as that of the memory cell may be performed. Thereby, it is possible to achieve an appropriate effect by corresponding to the respective operation state.

As described above, by performing the control of the substrate potential of the transistor of the memory cell, which is appropriate for the operation states of the semiconductor memory, such as high-speed writing, high-speed reading-out, memory cell stabilization, low leak, it enables to achieve an appropriate effect by corresponding to the respective operation state.

1. A semiconductor memory comprising:
a static-type memory cell constituted of a pair of access transistors formed with NMOS transistors, a pair of drive transistors formed with NMOS transistors, and a pair of load transistors formed with PMOS transistors; and
a substrate bias control unit which applies bias for increasing access speed to a substrate of any of said transistors when making access to said memory cell through adjusting electric current flown to a memory storage node in a common junction point of said three types of transistors.

2. The semiconductor memory according to claim 1, wherein said substrate bias control unit applies back bias to said substrate of said load transistor when writing data.

3. The semiconductor memory according to claim 1, wherein said substrate bias control unit applies back bias to said substrate of said drive transistor when writing data.

4. The semiconductor memory according to claim 1, wherein said substrate bias control unit applies forward bias to said substrate of said access transistor when writing data.

5. The semiconductor memory according to claim 1, wherein said substrate bias control unit, when writing data, applies back bias to said substrate of said load transistor and applies forward bias to said substrate of said access transistor.

6. The semiconductor memory according to claim 1, wherein said substrate bias control unit, when writing data, applies back bias to said substrate of said load transistor and applies back bias to said substrate of said drive transistor.

7. The semiconductor memory according to claim 1, wherein said substrate bias control unit, when writing data, applies forward bias to said substrate of said access transistor and applies back bias to said substrate of said drive transistor.

8. The semiconductor memory according to claim 1, wherein said substrate bias control unit, when writing data, applies back bias to said substrate of said load transistor, applies forward bias to said substrate of said access transistor, and applies back bias to said substrate of said drive transistor.

9. The semiconductor memory according to claim 1, wherein said substrate bias control unit applies forward bias to said substrate of said access transistor and said substrate of said drive transistor, respectively.

10. The semiconductor memory according to claim 1, wherein said substrate bias control unit, when writing data, applies back bias to said substrate of said load transistor, and applies forward bias to said substrate of said access transistor and said substrate of said drive transistor, respectively.

11. The semiconductor memory according to claim 1, wherein said substrate bias control unit applies forward bias to said substrate of said access transistor when reading out data.

12. The semiconductor memory according to claim 1, wherein said substrate bias control unit applies forward bias to said substrate of said drive transistor when reading out data.

13. The semiconductor memory according to claim 1, wherein said substrate bias control unit, when reading out data, applies forward bias to said substrate of said access transistor and said substrate of said drive transistor, respectively.

14. The semiconductor memory according to claim 1, wherein said substrate bias control unit applies forward bias to said substrate of said load transistor when reading out data.

15. The semiconductor memory according to claim 1, wherein said substrate bias control unit applies back bias to said substrate of said access transistor when reading out data.

16. The semiconductor memory according to claim 1, wherein said substrate bias control unit, when reading out data, applies forward bias to said substrate of said load transistor and applies back bias to said substrate of said access transistor.

17. The semiconductor memory according to claim 1, wherein said substrate bias control unit, when reading out data, applies forward bias to said substrate of said load transistor and applies forward bias to said substrate of said drive transistor.

18. The semiconductor memory according to claim 1, wherein said substrate bias control unit, when reading out data, applies back bias to said substrate of said access transistor and applies forward bias to said substrate of said drive transistor.

19. The semiconductor memory according to claim 1, wherein said substrate bias control unit, when reading out data, applies forward bias to said substrate of said load transistor, applies back bias to said substrate of said access transistor, and applies forward bias to said substrate of said drive transistor.

20. The semiconductor memory according to claim 1, wherein said substrate bias control unit, when reading out data, applies back bias to said substrate of said access transistor and said substrate of said drive transistor, respectively.

21. The semiconductor memory according to claim 1, wherein said substrate bias control unit, when reading out data, applies forward bias to said substrate of said load transistor, and applies back bias to said substrate of said access transistor and said substrate of said drive transistor, respectively.

22. The semiconductor memory according to claim 1, wherein:
said transistor substrate of said memory cell is separated by a column unit; and
said substrate bias control unit applies:
bias for increasing writing speed to a transistor substrate of a selected column in said memory cell when writing data;
bias for increasing reading-out speed to said transistor substrate of said selected column in said memory cell when reading out data; and
bias for improving stability to a transistor substrate of an unselected column in said memory cell.

23. The semiconductor memory according to claim 1, wherein:
said transistor substrate of said memory cell is separated by a column unit; and
said substrate bias control unit applies:
bias for increasing writing speed to a transistor substrate of a selected column in said memory cell when writing data;
bias for increasing reading-out speed to said transistor substrate of said selected column in said memory cell when reading out data; and
back bias to a transistor substrate of an unselected column in said memory cell.

24. The semiconductor memory according to claim 1, wherein:
said transistor substrate of said memory cell is separated by a row unit; and
said substrate bias control unit applies:
bias for increasing writing speed to a transistor substrate of a selected row in said memory cell when writing data;
bias for increasing reading-out speed to said transistor substrate of said selected row in said memory-cell when reading out data; and
bias for improving stability to a transistor substrate of an unselected row in said memory cell.

25. The semiconductor memory according to claim 1, wherein:
said transistor substrates of said memory cell is separated by a row unit; and
said substrate bias control unit applies:
bias for increasing writing speed to a transistor substrate of a selected row in said memory cell when writing data;
bias for increasing reading-out speed to said transistor substrate of said selected row in said memory cell when reading out data; and
back bias to a transistor substrate of an unselected row in said memory cell.

26. The semiconductor memory according to claim 1, wherein:
said transistor substrate of said memory cell is separated by a column unit and a row unit; and
said substrate bias control unit applies:
bias for increasing writing speed to transistor substrates of a selected column and a selected row in said memory cell when writing data;
bias for increasing reading-out speed to said transistor substrates of said selected column and said selected row in said memory cell when reading out data; and
bias for improving stability to transistor substrates of an unselected column and an unselected row in said memory cell.

27. The semiconductor memory according to claim 1, wherein:
said transistor substrate of said memory cell is separated by a column unit and a row unit; and
said substrate bias control unit applies:
bias for increasing writing speed to transistor substrates of a selected column and a selected row in said memory cell when writing data;
bias for increasing reading-out speed to said transistor substrates of said selected column and selected row in said memory cell when reading out data; and
back bias to transistor substrates of an unselected column and an unselected row in said memory cell.

28. A semiconductor memory, wherein said substrate bias control unit comprises: a high-speed writing mode which applies bias for increasing writing speed to said transistor substrate of said memory cell; a high-speed reading-out mode which applies bias for increasing reading out speed to said transistor substrate; a memory storing mode which applies bias for improving stability to said transistor substrate; and a low leak mode which applies back bias to said transistor substrate, said substrate bias control unit performing transition between each of said modes according to an operation state of a circuit.

29. The semiconductor memory according to claim 28, wherein said substrate bias control unit performs transition to said low leak mode except for time of reading-out and writing operations.

30. The semiconductor memory according to claim 28, wherein said substrate bias control unit performs transition between said high-speed writing mode, said high-speed reading-out mode, said memory storing mode and said low leak mode by predicting a circuit operation.

31. The semiconductor memory according to claim 28, wherein said substrate bias control unit performs transition between each of said modes by detecting a state of a special bit of a cache memory.

32. The semiconductor memory according to claim 28, wherein said substrate bias control unit performs transition between each of said modes by detecting redundancy relief information held by a redundancy relief memory.
